(19) United States
(12) Patent Application Publication
(10) Pub. No.: US 2025/0123554 A1
(43) Pub. Date: Apr. 17, 2025

(54) MASK DESIGN DEVICE FOR 3D PROXIMITY FIELD PATTERNING BASED ON ELECTRIC FIELD CONTROL, MASK FOR 3D PROXIMITY FIELD PATTERNING BASED ON ELECTRIC FIELD CONTROL, METHOD FOR MANUFACTURING A MASK FOR 3D PROXIMITY FIELD PATTERNING BASED ON ELECTRIC FIELD CONTROL AND NANO PATTERNING DEVICE

(71) Applicants: POSTECH RESEARCH AND BUSINESS DEVELOPMENT FOUNDATION, Pohang-si (KR); KOREA UNIVERSITY RESEARCH AND BUSINESS FOUNDATION, Seoul (KR)

(72) Inventors: Jun Suk RHO, Pohang-si (KR); Chi Hun LEE, Pohang-si (KR); Seok Woo JEON, Seoul (KR); Gwang Min BAE, Seoul (KR); Gun Ho CHANG, Seoul (KR)

(73) Assignees: POSTECH RESEARCH AND BUSINESS DEVELOPMENT FOUNDATION, Pohang-si (KR); KOREA UNIVERSITY RESEARCH AND BUSINESS FOUNDATION, Seoul (KR)

(21) Appl. No.: 18/763,294

(22) Filed: Jul. 3, 2024

(30) Foreign Application Priority Data
Oct. 12, 2023 (KR) 10-2023-0135822

(51) Int. Cl. G03F 1/70; G03F 7/00

(52) U.S. Cl. CPC G03F 1/70; G03F 7/0002; G03F 7/70433

(57) ABSTRACT

A mask design device for 3D proximity field pattering based on electric field control is provided. The mask design service, for producing a nanostructure having a constant period, may include: a material selector configured to select a material of the nanostructure having a specific refractive index; an objective function executor configured to execute an objective function based on a 2D electric field intensity map of the nanostructure formed from the material having a specific height and width; and an optimizer configured to set at least one of a period, the refractive index of the nanostructure, and the objective function, as an input variable, and configured to input the input variable into a predetermined algorithm to calculate design parameters of the nanostructure. A mask having the nanostructure, a method for manufacturing the mask, and a nano patterning device are also provided.

### CROSS-REFERENCE TO RELATED APPLICATIONS

This application claims the benefit of and priority to Korean Patent Application No. 10-2023-0135822, filed on Oct. 12, 2023, the entirety of which is incorporated herein by reference for all purposes.

### TECHNICAL FIELD

The present disclosure relates to a mask design, a mask, a method of manufacturing a mask, and a patterning device, and particularly to, for example, without limitation, a mask design device for three-dimensional (3D) proximity field pattering based on electric field control, a mask for 3D proximity field patterning based on electric field control, a method for manufacturing the mask for 3D proximity field patterning based on electric field control, and a nano patterning device.

### BACKGROUND

3D nanostructures show outstanding properties in various fields such as semiconductors, electrode materials, and structural materials, and accordingly, technology development for 3D nanostructure production is being actively conducted.

The conventional 3D nanostructure manufacturing technology is mainly based on dividing the 3D structure into 2D cross-sections and laminating them, rather than producing a target structure at once. This laminating method of manufacturing the 3D nanostructures has disadvantages in terms of process speed and mass productivity.

To solve these shortcomings, technologies to shape 3D nanostructures without repetitive processes have been developed, an example of which is proximity field nanopatterning.

The proximity field nanopatterning diffracts a single light source through a phase mask having a protruding structure, forms an interference fringe through interference between the diffracted lights, and transfers them to a photoresist to form a 3D nanostructure.

Nanostructures formed through proximity field nanopatterning can be used in various nanomaterials such as optical materials, structural materials, electrode materials, and sensors, and the demand for high-resolution nanostructures for excellent properties has been increasing. Since the nanostructure resolution of the proximity field nanopatterning is directly affected by the resolution of the interference pattern formed from the phase mask, optimization of the proximity field nanopatterning can be achieved by adjusting the structural design of the mask design.

The proximity field nanopatterning optimization approach described above is controlled through suppression of 0th order diffraction controlling a single variable. The suppression of the 0th order diffraction may maximize contrast by increasing the difference between the maximum and minimum values of the interference pattern.

However, the suppression of the 0th order diffraction has the disadvantage that it is difficult to control the electric field intensity in a locality, and the suppression of the 0th order diffraction not only increases the maximum value but also increases the electric field intensity in regions that interfere with formation of the target 3D nanostructure, resulting in reduced resolution.

The description in this background section should not be assumed to be prior art merely because it is mentioned in or associated with this section. The description in this background section includes information that describes one or more aspects of the subject technology, and the description in this section does not limit the invention.

### SUMMARY

The inventors of the present disclosure have recognized the problems and needs of the related art, have performed extensive research and experiments, and have developed a new invention. One or more aspects of the present disclosure are directed to devices and methods that substantially obviate one or more problems due to limitations and disadvantages of the related art, including the problems described above.

One or more aspects of the present disclosure are directed to providing a mask design device for three-dimensional (3D) proximity field pattering based on electric field control, where the mask design device is configured to calculate one or more design parameters for a mask for 3D proximity field patterning based on electric field control necessary to manufacture a 3D nanostructure having high resolution.

Further, in one or more aspects, the mask for 3D proximity field patterning based on electric field control configured with a 3D nanostructure having high resolution and the nano patterning device including the same may be provided.

According to an example embodiment, a mask design device for 3D proximity field pattering based on electric field control may produce a nanostructure having a period. The mask design device may include: a material selector configured to select a material of the nanostructure, the material having a specific refractive index; an objective function executor configured to execute an objective function based on a two-dimensional (2D) electric field intensity map of the nanostructure formed from the material, wherein the nanostructure has a specific height and width; and an optimizer configured to set at least one of the period, the refractive index of the material of the nanostructure, and the objective function, as an input variable, and configured to input the input variable into a predetermined algorithm to calculate design parameters of the nanostructure. In an example, the period may be constant.

Further, the mask design device for 3D proximity field pattering based on electric field control may be provided, wherein the objective function executor may select a plurality of points on the 2D electric field intensity map and execute the objective function based on the plurality of points.

Further a mask design device for 3D proximity field pattering based on electric field control may be provided, wherein the objective function executor may select a first point having the strongest electric field intensity in the 2D electric field intensity map, a second point having the weakest electric field intensity based on one axis, a third point having the weakest electric field intensity based on another axis, and a fourth point which is a center point of a virtual straight line connecting the second point and the third point, and execute the objective function based on the first to fourth points.

Further, a mask design device for 3D proximity field pattering based on electric field control may be provided, wherein the objective function for being executed by the objective function as executor is provided as

$$FOM = {E}_{max}^{2} + {E}_{diag}^{2} - {E}_{minx}^{2} - {E}_{minz}^{2} .$$

Here, Eₘₐₓ² is an electric field at the first point, E_{diag}² is an electric field at the fourth point, Eₘᵢₙₓ² is an electric field at the second point, fourth point, E_{minz}² mine is an electric field at the third point, and FOM is the objective function.

Further, the mask design device for 3D proximity field pattering based on electric field control may be provided, wherein the optimizer may calculate a height of the nanostructure, based on which the objective function is maximized, as at least one of the design parameters of the nanostructure.

Further, the mask design device for 3D proximity field pattering based on electric field control may be provided, wherein the optimizer may input the input variable into a particle swarm optimization (PSO) algorithm to calculate the design parameters of the nanostructure.

Further, the mask design device for 3D proximity field pattering based on electric field control may be provided, wherein the design parameters of the nanostructure calculated by the optimizer may include a height of the nanostructure, a fill factor of the nanostructure, and a shape of the nanostructure.

According to an example embodiment of the present disclosure, a mask for 3D proximity field patterning based on electric field control including the nanostructure formed based on the design parameters calculated by the mask design device for 3D proximity field pattering based on electric field control may be provided.

Further, the mask for 3D proximity field patterning based on electric field control may be provided, wherein the design parameters may comprise a height of the nanostructure, a fill factor, and a shape of the nanostructure.

According to an example embodiment of the present disclosure, a nano patterning device may include: a mask for 3D proximity field patterning based on electric field control, the mask formed based on the design parameters calculated by the mask design device for 3D proximity field pattering based on electric field control; a light source configured to irradiate light towards the mask for 3D proximity field patterning based on electric field control; and a photoresist configured to generate a pattern of the nanostructure, in response to the photoresist being irradiated with the light transmitted through the mask for 3D proximity field patterning based on electric field control and diffracted.

According to an example embodiment of the present disclosure, a method for manufacturing a mask for 3D proximity field patterning based on electric field control may include: providing a master mold formed using the design parameters calculated by the mask design device for 3D proximity field pattering based on electric field control or using variables complementary to the design parameters; depositing polyurethane acrylate on the master mold; and curing the polyurethane acrylate and then separating the polyurethane acrylate from the master mold to produce the mask for 3D proximity field patterning based on electric field control formed of the polyurethane acrylate.

Further, the method for manufacturing a mask for 3D proximity field patterning based on electric field control may include: depositing polydimethylsiloxane on the mask for 3D proximity field patterning based on electric field control; and providing a second mask for 3D proximity field patterning based on electric field control formed of the polydimethylsiloxane by curing the polydimethylsiloxane and then separating the second mask for 3D proximity field patterning based on electric field control formed of the polyurethane acrylate.

According to an example embodiment of the present disclosure, it is possible to calculate a design parameter of a mask for 3D proximity field patterning based on electric field control necessary for manufacturing a high-resolution 3D nanostructure.

Other apparatuses, devices, methods, features and advantages will be, or will become, apparent to one with skill in the art upon examination of the present disclosure. It is intended that all such apparatuses, devices, methods, features and advantages be included within this description, be within the scope of the present disclosure, and be protected by the claims. Nothing in this section should be taken as a limitation on the claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The accompanying drawings, which are included to provide a further understanding of the disclosure, are incorporated in and constitute a part of this disclosure, illustrate aspects and embodiments of the disclosure, and together with the description serve to explain principles and examples of the disclosure.

FIG. 1 is a conceptual view of a configuration of a mask design device for 3D proximity field pattering based on electric field control according to an example embodiment of the present disclosure.

FIG. 2 is an example of a conceptual view of a sub-configuration of a processor of a mask design device for 3D proximity field patterning based on electric field control of FIG. 1.

FIG. 3 is an example of a conceptual view of a nano patterning device including the mask for 3D proximity field patterning based on electric field control designed by the mask design device for 3D proximity field pattering based on electric field control of FIG. 1.

FIG. 4 shows an example of a 2D electric field intensity map of a nanostructure formed of a specific material.

FIGS. 5A to 5C illustrate examples of optimized design parameters (including fill factors and heights) obtained from execution of a particle swarm optimization (PSO) algorithm by an optimizer of FIG. 2.

FIG. 6 shows an example of diffraction efficiency of light passing through the mask for 3D proximity field patterning based on electric field control according to the height of the nanostructure.

FIGS. 7A to 7E show examples of distributions of 3D electric fields and x-z cross sections of the nanostructure for optimization of the design parameters.

FIG. 8 shows an example of a table including the design parameters, diffraction efficiency, collapse conditions, electric field information, and the like of a present example embodiment and a comparative example.

FIG. 9 is an example of a conceptual view of a method for manufacturing the mask for 3D proximity field patterning based on electric field control according to an example embodiment of the present disclosure.

FIG. 10 shows an example of a nano metasurface of a nanostructure produced by a mask design device for 3D proximity field pattering based on electric field control.

FIG. 11 shows an example of a performance evaluation of the nano metasurface of the nanostructure formed by the nano patterning device.

Throughout the drawings and the detailed description, unless otherwise described, the same drawing reference numerals should be understood to refer to the same elements, features, and structures. The sizes and thicknesses of layers, regions and elements, and depiction thereof may be exaggerated for illustration or convenience.

### DETAILED DESCRIPTION

Hereinafter, specific example embodiments of the present disclosure will be described in detail with reference to the drawings. In addition, in describing the present disclosure, the detailed description of known configurations or functions incorporated herein will be omitted if it is deemed that it may unnecessarily obscure the gist of the present disclosure.

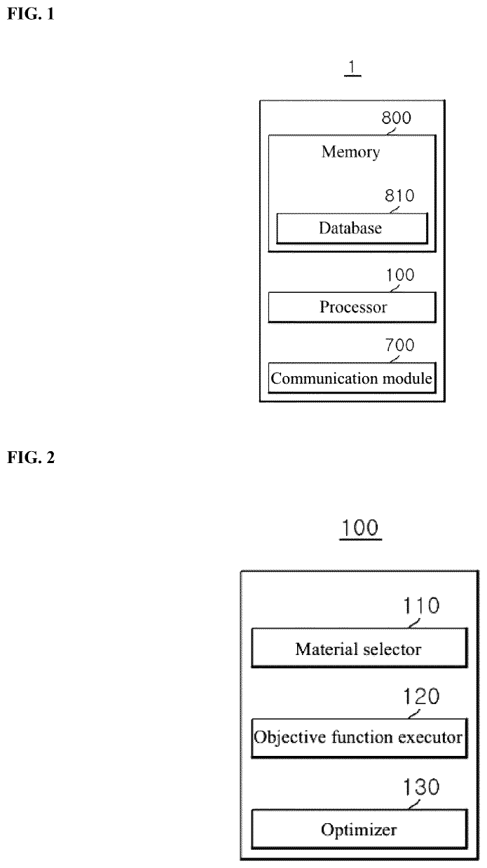

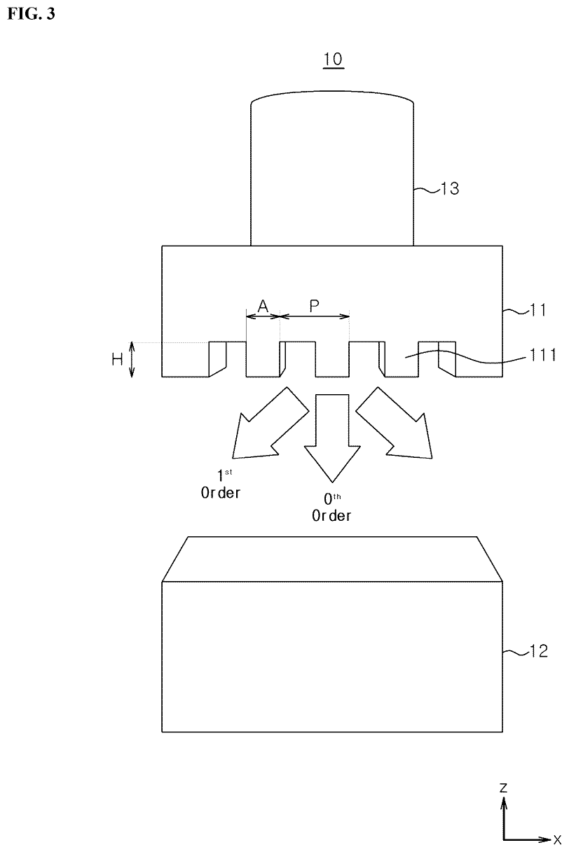

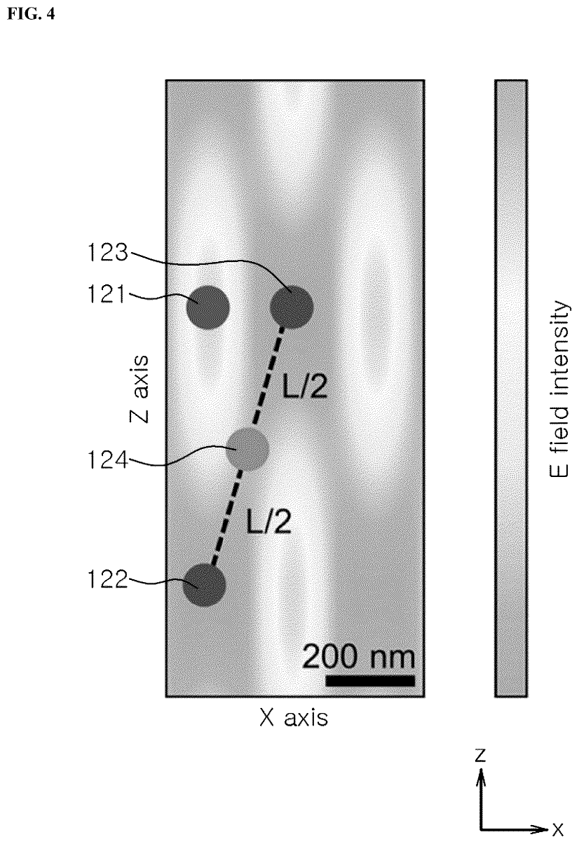

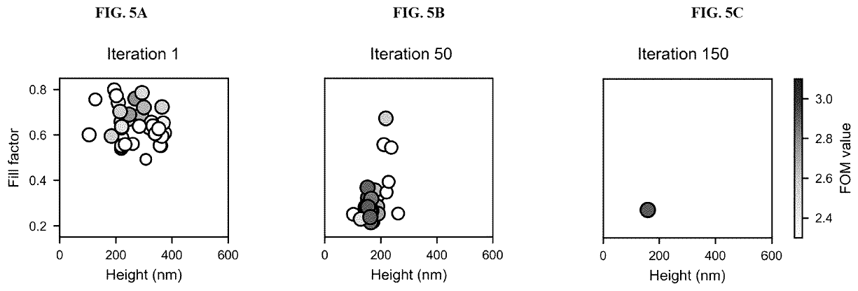

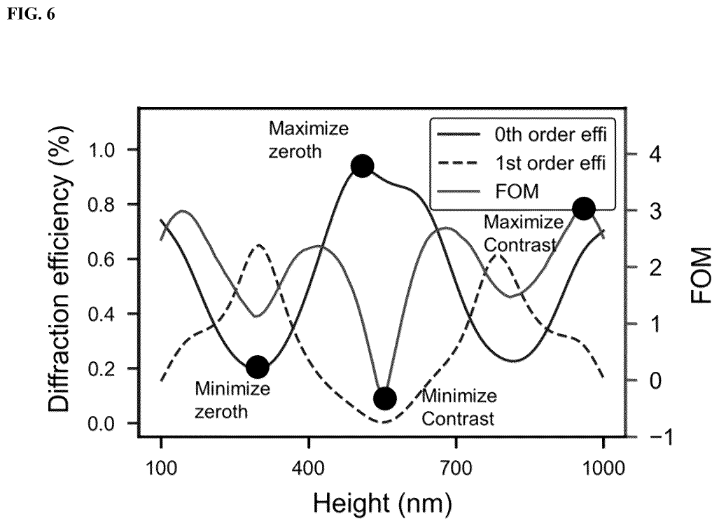

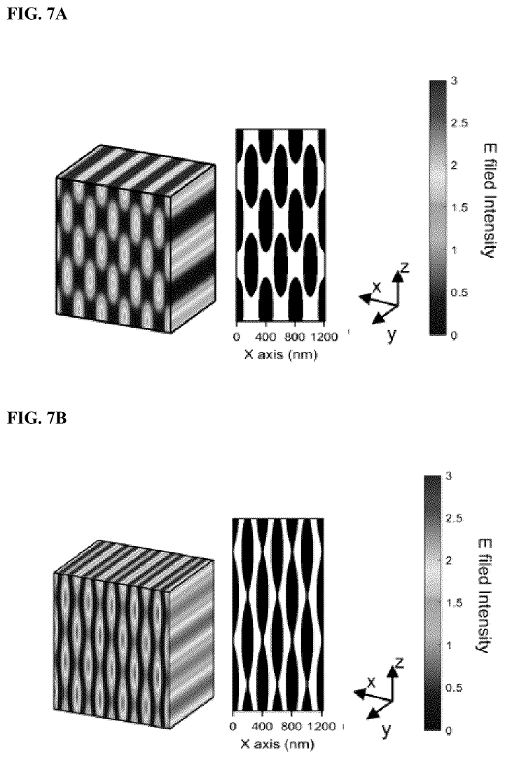

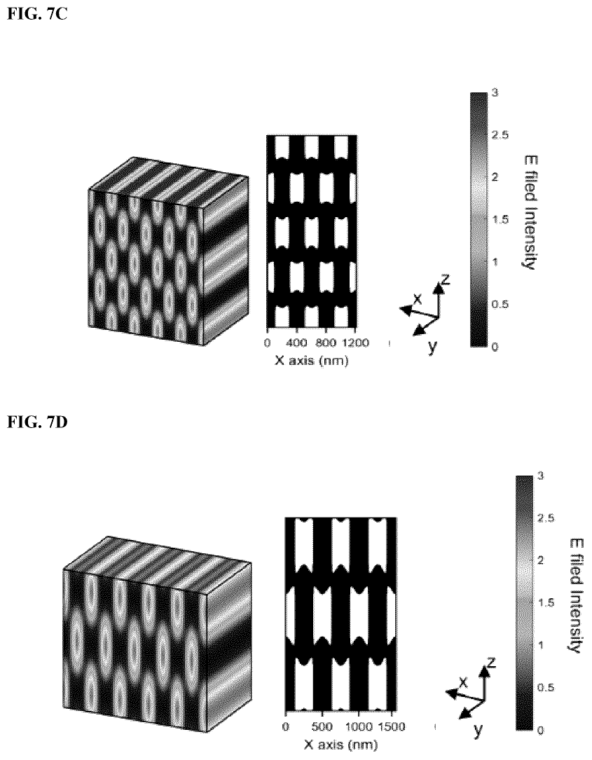

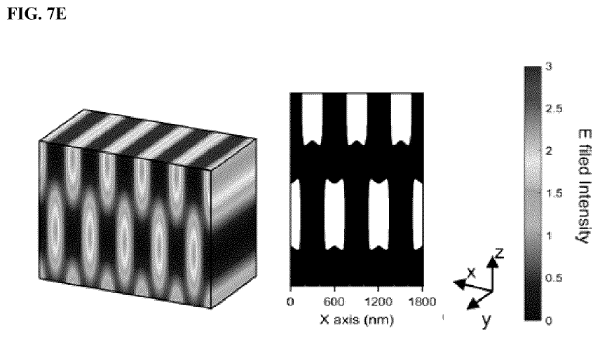

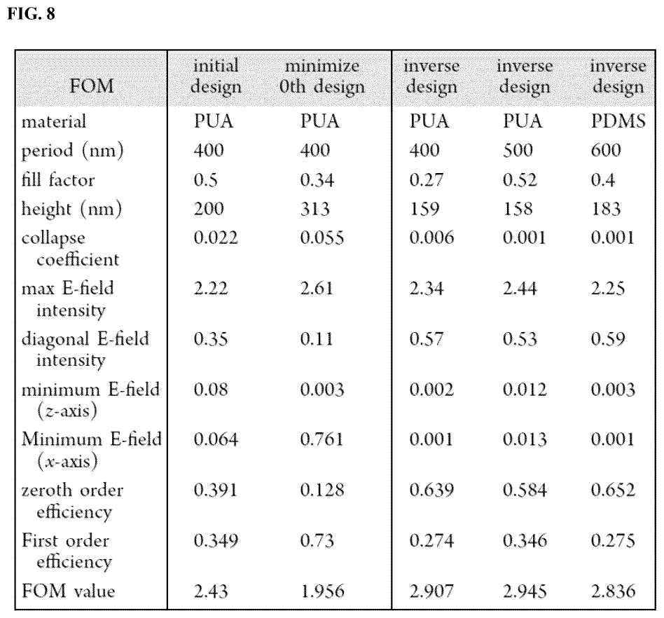

FIG. 1 is a conceptual view of a configuration of a mask design device for 3D proximity field pattering based on electric field control 1 according to an example embodiment of the present disclosure, FIG. 2 is an example of a conceptual view of a sub-configuration of a processor 100 of a mask for 3D proximity field patterning based on electric field control 11 of FIG. 1, FIG. 3 is an example of a conceptual view of a nano patterning device 10 including the mask for 3D proximity field patterning based on electric field control 11 designed by the mask design device for 3D proximity field pattering based on electric field control 1 of FIG. 1, FIG. 4 shows an example of a 2D electric field intensity map of a nanostructure 111 formed of a specific material, FIGS. 5A to 5C illustrate examples of optimized design parameters (including fill factors and heights (H)) obtained from execution of a particle swarm optimization (PSO) algorithm by an optimizer 130 of FIG. 2, FIG. 6 shows an example of diffraction efficiency of light passing through the mask for 3D proximity field patterning based on electric field control 11 according to the height (H) of the nanostructure 111, FIGS. 7A to 7E show examples of distributions of 3D electric fields and x-z cross sections of the nanostructure 111 for optimization of the design parameters, and FIG. 8 shows an example of a table including the design parameters, diffraction efficiency, collapse conditions, electric field information, and the like of a present example embodiment and a comparative example.

A mask design device for 3D proximity field pattering based on electric field control 1 may be referred to as, a mask design device 1 for 3D proximity field pattering based on electric field control, or a mask design device 1, and vice versa. A mask for 3D proximity field patterning based on electric field control 11 may be referred to as, a mask 11 for 3D proximity field patterning based on electric field control, or a mask 11, and vice versa. Further, a nanostructure 111 may include one or more nanostructures, or a plurality of nanostructures.

Referring to FIGS. 1 and 8, the mask design device for 3D proximity field pattering based on electric field control 1 can calculate optimized design parameters for designing the mask for 3D proximity field patterning based on electric field control 11.

In the present example embodiment, the target electric field intensity distribution is set and performs an inverse design to implement the target electric field intensity distribution through multi-variable control optimization using particle swarm optimization. Through this, the mask for 3D proximity field patterning based on electric field control 11 can be produced or derived, where the mask is configured with the nano metasurface 1000 of a 3D nanostructure with high resolution.

In one or more aspects, the present disclosure also enables preparation of the 3D nanostructure with high resolution using the mask for 3D proximity field patterning based on electric field control 11 optimized by the inverse designing.

The mask for 3D proximity field patterning based on electric field control 11 composed of periodic structures, and a setup of an interference field patterning can calculate the electric field after passing through the mask at high speeds based on rigorous coupled-wave analysis (RCWA).

By combining a RCWA calculation code and particle swarm optimization algorithm and adjusting the electric field of a specific portion, a high-contrast 3D electric field can be obtained. Based on this, a high-performance 3D nanostructure can be manufactured.

The mask for 3D proximity field patterning based on electric field control 11 may include a nanostructure 111 having a constant period (P) (see FIG. 3)

Each nanostructure 111 may be understood as a 3D shape (e.g., a rectangular parallelepiped shape) having a specific height (H) and width (A). For example, if the nanostructure 111 is provided in a shape of a rectangular parallelepiped, the nanostructure 111 may have the specific height (H) and width (A). Here, the other side of the nanostructure 111 is a variable that extends in a direction perpendicular to the xz plane, and can be excluded from input variables and the design parameters of the present example embodiment, which will be described later.

In the present example embodiment, the height (H) of the nanostructure 111 can be understood as a length measured in a z-axis direction with respect to FIG. 3, and the width (A) can be understood as a length measured in an x-axis direction with respect to FIG. 3.

In the present example embodiment, the shape of the nanostructure 111, which is the design parameter of the nanostructure 111 calculated in the mask design device for 3D proximity field pattering based on electric field control 1, may be in the shape of a rectangular parallelepiped. In the present example embodiment, the nanostructure 111 is described to be formed in a rectangular parallelepiped shape by way of an example. However, the present disclosure is not limited to this, and the shape of the nanostructure 111 may be provided or derived in a cylindrical shape depending on an input variable input in the mask design device for 3D proximity field pattering based on electric field control 1.

The mask design device for 3D proximity field patterning based on electric field control 1 may include a memory 800, a processor 100, and a communication module 700. The communication module 700 may include a physical communication interface.

The processor 100 may be configured to process instructions from a computer program by performing basic arithmetic, logic, and input/output operations. An instruction may be provided to the processor 100 from the memory 800 or the communication module 700.

The processor 100 of the mask design device for 3D proximity field patterning based on electric field control 1 can perform various functions such as inputting/outputting necessary data, processing data, managing data, and communicating using a communication network to derive the design parameters (e.g., a height (H) of the nanostructure 111, a fill factor, etc.) for manufacturing the nanostructure 111 of the mask for 3D proximity field patterning based on electric field control 11. Specific components of processor 100 to perform this are described later.

Further, at least some of the components of the processor 100 may include an artificial neural network pre-trained with machine learning. Further, the memory 800 may include a computer-readable recording medium, such as a random access memory (RAM), a read only memory (ROM), and a permanent mass storage device such as a disk drive.

The processor 100 of the mask design device for 3D proximity field pattering based on electric field control 1 according to the present example embodiment may include a material selector 110, an objective function executor 120, and an optimizer 130.

The mask for 3D proximity field patterning based on electric field control 11 shown in FIG. 3 can be manufactured based on the design parameters derived by the mask design device for 3D proximity field pattering based on electric field control 1.

The material selector 110 can select a material for the nanostructure 111 having a specific refractive index (n).

Here, a plurality of materials may be stored in a database 810, and the material selector 110 may retrieve one of the plurality of materials stored in the database 810. However, the present disclosure is not limited to this, and the material of the nanostructure 111 may be input directly into the material selector 110 of the processor 100 from an input device (e.g., keyboard, mouse, etc.). In this regard, a plurality of materials stored in the database 810 may include, or may be, a list of materials. The list of materials may include names, representations and/or descriptions of materials.

The material of the nanostructure 111 selected by the material selector 110 may include at least one of polyurethane acrylate (PUA) and polydimethylsiloxane (PDMA).

Here, the polydimethylsiloxane (PDMA) may include s-PDMS and h-PDMS, wherein the s-PDMS can be understood as a soft PDMS, and the h-PDMS can be understood as a hard PDMS.

The refractive index (n) of the polyurethane acrylate (PUA) may be provided as (or may be) 1.54, and the refractive index of the polydimethylsiloxane (PDMA) may be provided as (or may be) 1.4.

Further, the material of the nanostructure 111 may include titanium dioxide (TiO2), which may be provided with (or which may have) the refractive index of 2.87. For example, the nanostructure 111 may be formed of a physical material including titanium dioxide.

The objective function executor 120 can execute an objective function (FOM) based on the 2D electric field intensity map of the nanostructure 111 with a specific height (H) and width (A).

FIG. 4 shows an example of a 2D electric field intensity map of a nanostructure formed of a specific material.

Here, the 2D electric field intensity map can be understood as an inversely designed electric field intensity map for high-contrast 3D nanopatterning.

The objective function executor 120 may select a plurality of points on the 2D electric field intensity map, such as the 2D electric field intensity map shown in FIG. 4, and execute the objective function (FOM) based on the plurality of points.

Specifically, the objective function executor 120 selects a first point 121 having the strongest electric field intensity in the 2D electric field intensity map, a second point 122 having the weakest electric field intensity based on one axis, a third point 123 having the weakest electric field intensity based on another axis, and a fourth point 124 is which is a center point of a virtual straight line connecting the second point 122 and the third point 123. The objective function (FOM) can be executed based on the first to fourth points 121, 122, 123, and 124.

Here, the second point 122 can be understood as an area where the intensity of the electric field is weakest with respect to the x-axis, and the third point 123 can be understood as an area where the intensity of the electric field is weakest with respect to the z-axis.

Here, the objective function (FOM) may be stored in the database 810, and the objective function executor 120 may retrieve the objective function (FOM) stored in the database 810.

Further, the objective function (FOM) executed by the objective function executor 120 is as shown in Formula 1 below.

$$FOM = {E}_{max}^{2} + {E}_{diag}^{2} - {E}_{minx}^{2} - {E}_{minz}^{2} \qquad [ Formula 1 ]$$

Here, Eₘₐₓ² can be understood as the electric field measured at the first point where the intensity of the electric field is the strongest in the 2D electric field intensity map.

E_{diag}² can be understood as an electric field measured at the fourth point which represents the intensity of a midpoint between two points where the electric field intensity is the weakest. Eₘᵢₙₓ² can be understood as an electric field measured at the second point where the electric field intensity is the weakest based on one axis (x-axis). E_{minz}² can be understood as an electric field measured at the third point where the electric field intensity is the weakest based on another axis (z-axis).

Here, E_{diag}² can be understood as a term to increase uniformity of square-shaped patterns, and a high value of the objective function (FOM) can provide an ideal rectangular grid shape regardless of the diffraction order efficiency.

The optimizer 130 may set at least one of the period (P), the refractive index (n), and the objective function (FOM) of the nanostructure 111 as an input variable, and may input the input variable into a preset algorithm to calculate the design parameters of the nanostructure 111.

For example, the optimizer 130 can use the PSO algorithm to calculate the design parameters of the nanostructure 111. By this, a shape of the mask for 3D proximity field patterning based on electric field control 11 optimized for the high-contrast 3D nanopatterning can be obtained.

Here, the PSO algorithm is one of the known global optimization methods that does not use gradient information and can therefore be applied to non-differentiable problems.

The PSO algorithm easily falls into local optima and has a low convergence rate in the iterative process. In order to supplement the above problem, internal parameters of the PSO algorithm can be decided and boundary conditions can be set.

Here, the PSO algorithm may be referred to as the particle swarm optimization algorithm, and by setting actual designable conditions (structure height limit ratio, minimum structure size) as boundary conditions, a structure configured to maximize the objective function (FOM) can be found among processable designs of the mask for 3D proximity field patterning based on electric field control 11.

In the case of a conventional optimized structure, compared to a mask design developed through minimization of 0th order diffraction, the mask for 3D proximity field patterning based on electric field control 11 of the present example embodiment was able to secure a higher electric field intensity contrast, and when a portion exceeding a threshold value was removed, there is an advantage of being able to obtain a more distinct 3D pattern on an expected binary structure.

The PSO algorithm uses multiple particles to find optimal parameters. The position of each particle represents the design parameter, and the value may be the objective function (FOM) calculated through a simulation. By sharing personal and global minimum information in every iteration, all particles can update their respective positions. During the iteration, several particles may be excluded from initial boundary conditions.

In the present example embodiment, the optimizer 130 can apply two types of conditions to the PSO algorithm.

The optimizer 130 can apply the maximum and minimum values of the design parameters, including the fill factor and height (H), as boundary conditions for the PSO algorithm. For example, the boundary conditions can be set to a minimum height (H) value of 100 nm, a maximum height (H) value of 800 nm, a minimum fill factor of 0.2, and a maximum fill factor of 0.8.

Further, the optimizer 130 can apply a collapse condition to the PSO algorithm.

In case of microcontact printing-based fabrications, the nanostructure 111 requires consideration of residual stress, which varies depending on the material and geometry. During the iteration, if some particles exceed the collapse condition, the exceeding particles are removed and regenerated within the initial boundary conditions. Thus, the PSO algorithm can be executed by modifying the internal parameters, and since the PSO algorithm is a known algorithm, detailed description will be omitted.

The design parameters of the nanostructure 111 calculated by the PSO algorithm may include the height (H) of the nanostructure 111, the fill factor of the nanostructure 111, and the shape of the nanostructure 111.

Here, the fill factor can be understood as the ratio of the height (H) and width (A) of the nanostructure 111 (width (A) of the nanostructure 111/height (H) of the nanostructure 111).

FIGS. 5A to 5C illustrate examples of diagrams in which the optimized design parameters (including fill factors and heights (H)) obtained from execution of the PSO algorithm are derived.

In addition, the optimizer 130 can calculate the height (H) of the nanostructure 111 in which the objective function (FOM) is maximized, into the design parameters of the nanostructure 111.

Referring to FIG. 6, it can be understood that the diffraction efficiency according to the height (H) of the nanostructure 111 is the highest when the objective function (FOM) is at its maximum point. In FIG. 5, a red solid line represents the objective function (FOM) of the present example embodiment, and a blue solid line and a blue dotted line represent the efficiency of a 0th order and a 1st order, respectively, as comparative examples.

The period (P) of the nanostructure 111 used in FIG. 6 may be 400 nm, and the fill factor may be 0.5.

FIGS. 7A to 7E show examples of distributions of 3D electric fields and x-z cross sections of the nanostructure 111 for optimization of the design parameters.

FIG. 7A is a comparative example showing a distribution of the 3D electric field of the nanostructure 111 having 400 nm period (P), 0.5 fill factor, and 200 nm height (H) as initial design parameters. Low contrast on the x-axis can be understood as a factor interrupting the hexagonal lattice shape.

FIG. 7B is a comparative example with a minimized 0th order efficiency design, showing a distribution of the 3D electric field of the nanostructure 111 having 400 nm period (P), 0.34 fill factor, and 313 nm height (H) as the design parameters. Likewise, low contrast on the x-axis can be understood as a factor that interrupts the hexagonal lattice shape.

FIG. 7C is an example embodiment of the present disclosure showing a distribution of the 3D electric field of the nanostructure 111 having 400 nm period (P), 0.27 fill factor, and 159 nm height (H) as the design parameters. It can be seen that an example embodiment of the present disclosure represents a hexagonal lattice. FIG. 7D is an example embodiment of the present disclosure showing a distribution of the 3D electric field of the nanostructure 111 having 500 nm period (P), 0.52 fill factor, and 158 nm height (H) as the design parameters. The nanostructure 111 of FIGS. 7A to 7D may use polyurethane acrylate (PUA) as a material. FIG. 7E is an example embodiment of the present disclosure with polydimethylsiloxane (PDMA) as a material, showing a distribution of the 3D electric field of the nanostructure 111 having a 600 nm period (P), a 0.4 fill factor, and a 183 nm height (H) as the design parameters.

As can be seen from the electric field distribution and binarization results shown in FIG. 7C, FIG. 7D and FIG. 7E, a hexagonal lattice hole arrangement can be formed through diffraction control.

FIG. 8 shows an example of a table including the design parameters, diffraction efficiency, collapse conditions, electric field information, and the like of a present example embodiment and comparative example.

It may be understood that those labeled as “inverse design” in FIG. 8 refer to the present example embodiment.

Referring to FIG. 8, the materials of the nanostructure 111 designed by the mask design device for 3D proximity field pattering based on electric field control 1 may be polyurethane acrylate (PUA) and polydimethylsiloxane (PDMA).

Further, the nanostructure 111 shown in FIG. 8 may be provided to have a period (P) from 400 nm to 600 nm, a fill factor from 0.27 to 0.52, and a height (H) from 158 nm to 183 nm. Here, the objective function (FOM) value may be provided from 2.836 to 2.945.

Specifically, the nanostructure 111 of an example embodiment of the present disclosure shown in FIG. 8 may be provided to have a material of polyurethane acrylate (PUA), a period (P) of 400 nm, a fill factor of 0.27, a height of 159 nm, and an objective function (FOM) value of 2.907.

In addition, the nanostructure 111 of another example embodiment of the present disclosure may be provided to have a material of polyurethane acrylate (PUA), a period (P) of 500 nm, a fill factor of 0.52, a height of 158 nm, and an objective function (FOM) value of 2.945.

Further, the nanostructure 111 of yet another example embodiment of the present disclosure may be provided to have a material of polydimethylsiloxane (PDMA), a period (P) of 600 nm, a fill factor of 0.4, a height of 183 nm, and an objective function (FOM) value of 2.836.

The mask for 3D proximity field patterning based on electric field control 11 including the nanostructure designed to have a design parameter calculated in the optimizer 130 may generate an interference field by rotating an incident light.

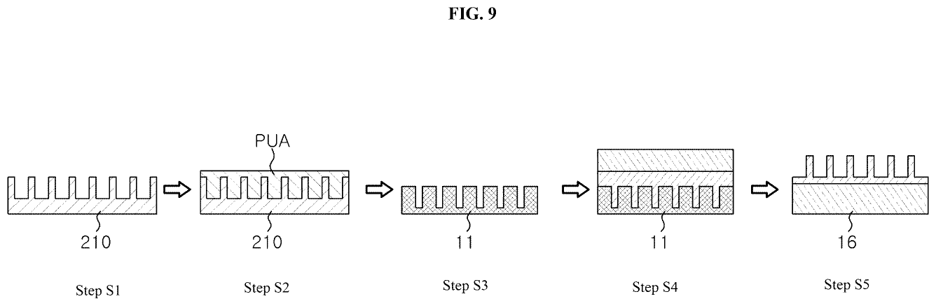

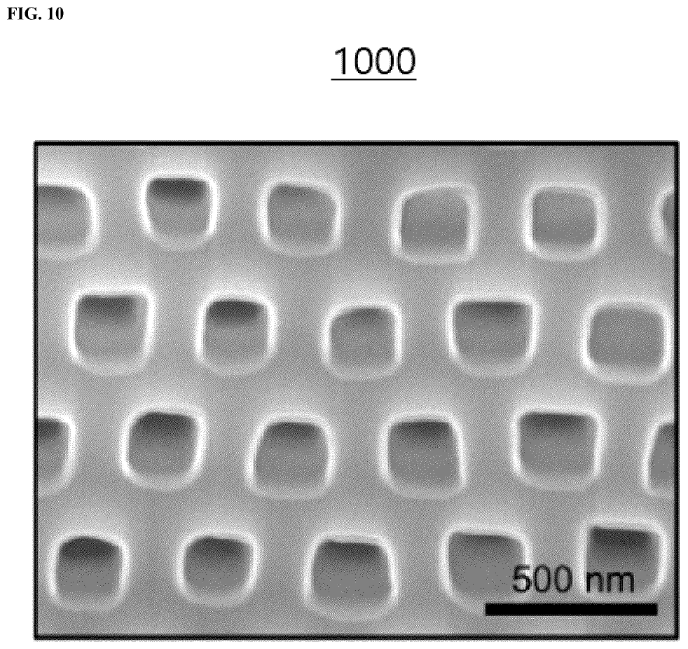

FIG. 9 is an example of a conceptual view of the method for manufacturing the mask for 3D proximity field patterning based on electric field control, and FIG. 10 shows an example of a nano metasurface 1000 of the nanostructure produced by the mask design device for 3D proximity field pattering based on electric field control 1.

Referring to FIGS. 1 to 9, the method for manufacturing the mask for 3D proximity field patterning based on electric field control may include a step S1 of providing the design parameters calculated by the mask design device for 3D proximity field pattering based on electric field control 1 or providing a master mold 210 formed using the design parameters calculated by the mask design device for 3D proximity field pattering based on electric field control or using variables complementary to the design parameters; a step S2 of depositing polyurethane acrylate (PUA) on the master mold 210; and a step S3 of curing the polyurethane acrylate (PUA) and then separating it from the master mold 210 to form the mask for 3D proximity field patterning based on electric field control 11 formed of the polyurethane acrylate (PUA).

In step S1, the design parameters and the complementary variables can be understood as variables designed so that the mask for 3D proximity field patterning based on electric field control 11 has the above-described design parameters.

To describe the step S1 in more detail, a 500 μm thick Si wafer can be patterned using a standard electron beam lithography process (ELIONIX, ELS-7800, acceleration voltage: 80 kV, beam current: 100 pA, size limit 500 μm×500 μm2).

After an exposure process, a mask pattern is transferred onto a positive electron beam resist (495 PMMA A2, Micro-Chem), and a resist pattern can be developed by exposing in a methyl isobutyl ketone/IPA (1:3) solution at 0° C. for 15 minutes. Additionally, a 30 nm thick chromium (Cr) mask can be deposited using an electron beam evaporator (KVT, KVE-E4000), followed by a lift-off process of immersing in acetone at 75° C. for 15 minutes and performing an ultrasonic treatment at 45 Hz for 4 minutes. Then, the master mold 210 can be generated by transferring the Cr mask pattern onto the Si wafer using a dry etching process (Dry Etcher, DMS) and then removing the remaining Cr mask using a Cr etchant (CR-7).

Then, the step S2 of depositing polyurethane acrylate (PUA) on the master mold 210 may be performed.

Thereafter, a step S3 of curing the polyurethane acrylate (PUA) and then separating it from the master mold 210 to form the mask for 3D proximity field patterning based on electric field control 11 formed of the polyurethane acrylate (PUA) may be performed.

In the case of the mask for 3D proximity field patterning based on electric field control 11, the polyurethane acrylate (PUA) is dropped into a silicon mold formed through an etching process and covered with a transparent glass substrate. A first crosslinking is formed through ultraviolet (UV) exposure of the silicon mold connected to the polyurethane acrylate (PUA) by the glass substrate, and the substrate is separated from the mold to form a PUA concave-convex structure on the substrate. Thereafter, a complete crosslinking can be formed through sufficient secondary UV exposure.

Further, the method for manufacturing the mask for 3D proximity field patterning based on electric field control may further include a step S4 of depositing polydimethylsiloxane (PDMA) on the mask for 3D proximity field patterning based on electric field control 11; and a step S5 of forming the mask for 3D proximity field patterning based on electric field control 11 formed of polydimethylsiloxane (PDMA) by curing the polydimethylsiloxane (PDMA) and then separating the mask for 3D proximity field patterning based on electric field control 11 formed of the polyurethane acrylate (PUA).

The step S4 may include a step of depositing h-PDMS on the mask for 3D proximity field patterning based on electric field control 11, and a step of depositing s-PDMS on an upper portion of the h-PDMS.

A mask for 3D proximity field patterning based on electric field control 16 produced by this process can be formed from the h-PDMS and the s-PDMS as materials.

The mask for 3D proximity field patterning based on electric field control 16 can be manufactured by using the PDMS with two different mechanical strengths on the above described mask for 3D proximity field patterning based on electric field control 11.

The PDMS used in the mask for 3D proximity field patterning based on electric field control 16 may include the h-PDMS (hard PDMS), which has relatively high mechanical strength, and the s-PDMS (soft PDMS), which has relatively low mechanical strength.

Here, the h-PDMS is solidified using VDT-731, HMS-301 (Gelest). Further, the s-PDMS is produced by mixing a Sylgard 184-based PDMS elastomer with a 10:1 ratio of base and hardener and then curing it. Further, the mask for 3D proximity field patterning based on electric field control 16 can be completed by spin-coating the h-PDMS on the manufactured mask for 3D proximity field patterning based on electric field control 11 mold and pouring the s-PDMS to cure before it is completely cured.

The mask for 3D proximity field patterning based on electric field control 11 formed of the polyurethane acrylate (PUA) can be formed by the steps S1 to S3, and the mask for 3D proximity field patterning based on electric field control 16 formed of the polydimethylsiloxane (PDMA) can be formed in the steps S1 to S5.

According to another example embodiment of the present invention, a nano patterning device 10 may include: a mask for 3D proximity field patterning based on electric field control 11 including a nanostructure 111 manufactured using design parameters calculated by a mask design device for 3D proximity field pattering based on electric field control 1; a light source 13 configured to irradiate light towards the mask for 3D proximity field patterning based on electric field control 11; and a photoresist 12 in which a pattern of the nanostructure 111 is generated by being irradiated with light transmitted through the mask for 3D proximity field patterning based on electric field control 11 and diffracted, may be provided (see FIG. 3).

Here, the nanostructure 111 may be disposed in direct contact or in non-contact with the photoresist 12.

The mask for 3D proximity field patterning based on electric field control 11 is based on including a nanostructure 111 with periodicity, but is not limited to this and can have any structure that can diffract incident light to form a targeted interference pattern.

If mask for 3D proximity field patterning based on electric field control 11 has a periodic structure, the controllable structural elements of the mask for 3D proximity field patterning based on electric field control 11 may include a period (P), a fill factor, and a height (H) of the nanostructure 111. Here, the fill factor can be understood as a ratio occupied by a protruding structure.

Materials that make up (or form) the mask for 3D proximity field patterning based on electric field control 11 may include polymers such as PDMS (Polydimethylsiloxane, where n is about 1.4), PUA (Polyurethane acrylate, where n is about 1.54), or high refractive index materials such as TiO2 (where n is about 2.87). In this regard, “n” may refer to a refractive index.

Depending on the material that makes up (or forms) the mask for 3D proximity field patterning based on electric field control 11, a contact or non-contact state between the mask for 3D proximity field patterning based on electric field control 11 and a photoresist 12 is determined. In the non-contact mode, light can be propagated through an air layer or elastomer.

A negative-tone photoresist such as SU-8 (where n is about 1.6) and a positive-tone photoresist of AZ series can be used for the photoresist 12, but all other materials used in an exposure process can be used.

The mask for 3D proximity field patterning based on electric field control 11 has been explained in detail above, so the detailed explanation thereof will be omitted.

The light source 13 can irradiate light having a wavelength range of 300 nm to 400 nm, preferably 355 nm, toward the mask for 3D proximity field patterning based on electric field control 11.

The light is transmitted through the mask for 3D proximity field patterning based on electric field control 11 and diffracted, which may generate an interference field.

The light transmitted through the mask for 3D proximity field patterning based on electric field control 11 may be diffracted into light having a 0th order, a 1st order diffraction, a 2nd order diffraction, and an nth order diffraction, where n may be a whole number.

The light transmitted through the mask for 3D proximity field patterning based on electric field control 11 may be exposed to a substrate on which the photoresist 12 is spin-coated to a thickness of 5 to 10 μm. After exposure, it can be heated at 55 degrees Celsius for 15 minutes to form a stable crosslinking. Thereafter, the photoresist 12 can be developed for about 20 minutes and then cleaned with an ethanol solution.

Further, for the negative tone photoresist, only higher intensity regions of the interference pattern formed from the mask for 3D proximity field patterning based on electric field control 11 are crosslinked, remaining in a 3D nanostructure. After exposure and development, the portion where crosslinking has not occurred can be removed, leaving only the formed 3D nanostructure on the substrate. A heating or development step may be added to form a stable 3D nanostructure after exposure.

Through this process, the nano metasurface 1000 with patterning formed as shown in FIG. 10 can be created.

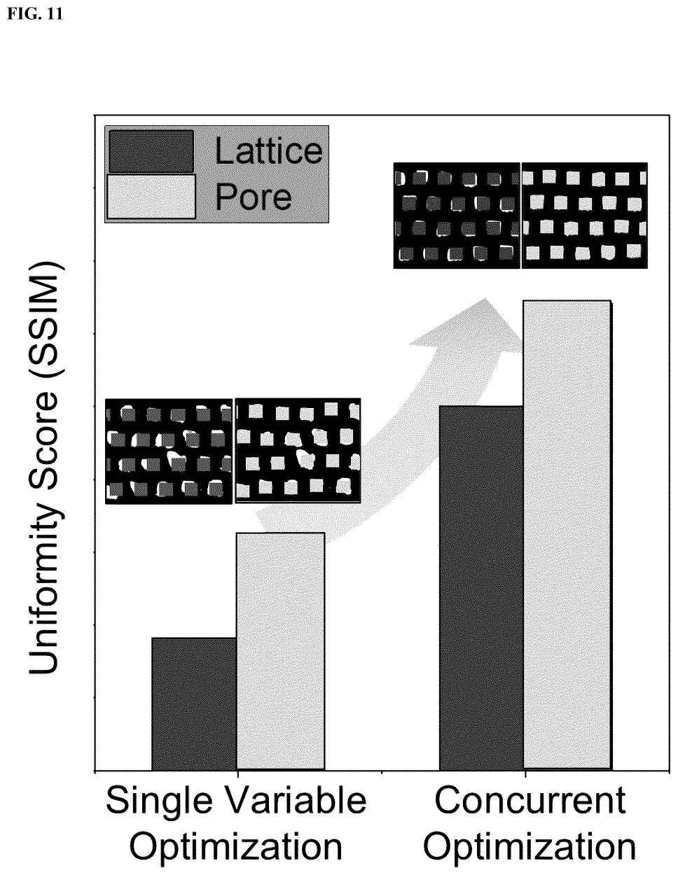

FIG. 11 shows an example of a performance evaluation of the nano metasurface 1000 of the nanostructure formed by the nano patterning device 10.

FIG. 11 shows a quantitative score of the completeness of a nanostructure, based on a structural similarity index measure (SSIM), with two types of idealized structures (idealized arrangement to evaluate the arrangement (Lattice)/idealized nanohole to evaluate the shape of nanoholes (Pore)) to compare both metrics.

The nanostructure manufactured using the nano patterning device 10 of the present example embodiment can obtain a more uniform shape and more uniform arrangement than a structure manufactured based on conventional zero-order diffraction minimization.

In the present example embodiment, the user can inversely find a structure that satisfies the electric field in a specific portion, and can be utilized to create various patterns by setting different high and low points of the electric field. Through this, the present disclosure can be utilized in various application fields of the 3D nanostructure such as optical materials and structural materials.

Although the mask design device for 3D proximity field pattering based on electric field control, the mask for 3D proximity field patterning based on electric field control, the method for manufacturing the mask for 3D proximity field patterning based on electric field control, and the nano patterning device according to the example embodiments of the present disclosure have been described as specific example embodiments, there are merely examples, and the present disclosure is not limited thereto, and should be construed as having the broadest possible scope in accordance with the present disclosure. Those skilled in the art may combine and substitute the disclosed example embodiments and practice embodiments not shown, without departing from the scope of the present disclosure. In addition, those skilled in the art may readily make changes or modifications to the example embodiments disclosed herein, and it is apparent that such changes or modifications are within the scope of the present disclosure.

Headings and subheadings, if any, are used for convenience only and do not limit the invention. The word “exemplary” is used to mean serving as an example or illustration. Any implementation described herein as an “example” is not necessarily to be construed as preferred or advantageous over other implementations. Relational terms such as first and second and the like may be used simply for ease of understanding without necessarily requiring or implying any actual relationship or order between elements or actions and without necessarily requiring or implying that they have different characteristics unless stated otherwise.

Phrases such as an aspect, the aspect, another aspect, some aspects, one or more aspects, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A phrase “at least one of” preceding a series of items, with the terms “and” or “or” to separate any of the items, modifies the list as a whole, rather than each member of the list. The phrase “at least one of” does not require selection of at least one item; rather, the phrase allows a meaning that includes at least one of any one of the items, and/or at least one of any combination of the items, and/or at least one of each of the items. By way of example, each of the phrases “at least one of A, B, and C” and “at least one of A, B, or C” may refer to only A, only B, or only C; any combination of A, B, and C; and/or at least one of each of A, B, and C.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C. Furthermore, an expression “element A/element B” may be understood as element A and/or element B.

In one or more aspects, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements.

In one or more examples, the number of elements may be two. In one or more examples, the number of elements may be more than two.

In one or more aspects, the terms “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

Features of various embodiments of the present disclosure may be partially or wholly coupled to or combined with each other and may be variously inter-operated, linked or driven together. The embodiments of the present disclosure may be carried out independently from each other or may be carried out together in a co-dependent or related relationship. In one or more aspects, the components of each apparatus according to various embodiments of the present disclosure are operatively coupled and configured.

Unless otherwise defined, the terms (including technical and scientific terms) used herein have the same meaning as commonly understood by one of ordinary skill in the art to which example embodiments belong. It is further understood that terms, such as those defined in commonly used dictionaries, should be interpreted as having a meaning that is, for example, consistent with their meaning in the context of the relevant art and should not be interpreted in an idealized or overly formal sense unless expressly defined otherwise herein.

In describing a positional relationship, where the positional relationship between two parts is described, for example, using “on,” “over,” “under,” “above,” “below,” “beneath,” “near,” “close to,” or “adjacent to,” “beside,” “next to,” or the like, one or more other parts may be located between the two parts unless a more limiting term, such as “immediate (ly),” “direct (ly),” or “close (ly),” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

It is understood that the specific order or hierarchy of steps, operations, or processes disclosed is an illustration of exemplary approaches. Unless explicitly stated otherwise, it is understood that the specific order or hierarchy of steps, operations, or processes may be performed in different order, with the exception of steps and/or operations necessarily occurring in a particular order. Some of the steps, operations, or processes may be performed simultaneously. The accompanying method claims, if any, present elements of the various steps, operations or processes in a sample order, and are not meant to be limited to the specific order or hierarchy presented. These may be performed in serial, linearly, in parallel or in different order. It should be understood that the described instructions, operations, and systems can generally be integrated together in a single software/hardware product or packaged into multiple software/hardware products.

In describing a temporal relationship, when the temporal order is described as, for example, “after,” “subsequent,” “next,” “before,” “preceding,” “prior to,” or the like, a case that is not consecutive or not sequential may be included unless a more limiting term, such as “just,” “immediate (ly),” or “direct (ly),” is used.

It is understood that, although the term “first,” “second,” or the like may be used herein to describe various elements, these elements should not be limited by these terms. These terms are only used to distinguish one element from another. For example, a first element could be a second element, and, similarly, a second element could be a first element, without departing from the scope of the present disclosure. Furthermore, the first element, the second element, and the like may be arbitrarily named according to the convenience of those skilled in the art without departing from the scope of the present disclosure.

In describing elements of the present disclosure, the terms “first,” “second,” “A,” “B,” “(a),” “(b),” or the like may be used. These terms are intended to identify the corresponding element(s) from the other element(s), and these are not used to define the essence, basis, order, or number of the elements.

In one or more examples, when an element is “connected” or “coupled” to another element, the element can be directly connected or coupled to another element, and can be indirectly connected or coupled to another element with one or more intervening elements disposed or interposed between the elements, unless otherwise specified.

The disclosure is provided to enable any person skilled in the art to practice the various aspects described herein. In some instances, when a detailed description of well-known functions or configurations may unnecessarily obscure aspects of the present disclosure, the detailed description thereof may have been omitted. The disclosure provides various examples of the subject technology, and the subject technology is not limited to these examples. Various modifications to these aspects will be readily apparent to those skilled in the art, and the principles described herein may be applied to other aspects.

Unless stated otherwise, like reference numerals may refer to like elements throughout even when they are shown in different drawings. In one or more aspects, identical elements (or elements with identical names) in different drawings may have the same or substantially the same functions and properties unless stated otherwise. Names of the respective elements used in the following explanations are selected only for convenience and may be thus different from those used in actual products.

The shapes, sizes, areas, ratios, numbers, and the like disclosed in the drawings for describing implementations of the present disclosure are merely examples, and thus, the present disclosure is not limited to the illustrated details.

When the term “comprise,” “have,” “include,” “contain,” “constitute,” or the like is used with respect to one or more elements, one or more other elements may be added unless a term such as “only” or the like is used. The terms used in the present disclosure are merely used in order to describe particular embodiments, and are not intended to limit the scope of the present disclosure. The terms used herein are merely used in order to describe example embodiments, and are not intended to limit the scope of the present disclosure. The terms of a singular form may include plural forms unless the context clearly indicates otherwise. An element proceeded by “a,” “an,” “the,” or “said” does not, without further constraints, preclude the existence of additional elements.

In one or more aspects, an element, feature, or corresponding information (e.g., a level, range, dimension, size, or the like) is construed as including an error or tolerance range even where no explicit description of such an error or tolerance range is provided. An error or tolerance range may be caused by various factors (e.g., process factors, internal or external impact, or the like). Furthermore, while the subject disclosure may provide many example ranges and values, these are non-limiting examples, and other ranges and values are within the scope of the subject technology.

All structural and functional equivalents to the elements of the various aspects described throughout the disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.”

The title, background, brief description of the drawings, abstract, and drawings are hereby incorporated into the disclosure and are provided as illustrative examples of the disclosure, not as restrictive descriptions. It is submitted with the understanding that they will not be used to limit the scope or meaning of the claims. In addition, in the detailed description, it can be seen that the description provides illustrative examples and the various features are grouped together in various implementations for the purpose of streamlining the disclosure. The method of disclosure is not to be interpreted as reflecting an intention that the claimed subject matter requires more features than are expressly recited in each claim. Rather, as the claims reflect, inventive subject matter lies in less than all features of a single disclosed configuration or operation. The claims are hereby incorporated into the detailed description, with each claim standing on its own as a separately claimed subject matter.

The claims are not intended to be limited to the aspects described herein, but are to be accorded the full scope consistent with the claims and to encompass all legal equivalents. Notwithstanding, none of the claims are intended to embrace subject matter that fails to satisfy the requirements of the applicable patent law, nor should they be interpreted in such a way.

What is claimed is:

1. A mask design device for three-dimensional (3D) proximity field pattering based on electric field control, the mask design device for producing a nanostructure having a period, the mask design device comprising:
a material selector configured to select a material of the nanostructure, the material having a specific refractive index;
an objective function executor configured to execute an objective function based on a two-dimensional (2D) electric field intensity map of the nanostructure formed from the material, wherein the nanostructure has a specific height and width; and
an optimizer configured to set at least one of the period of the nanostructure, the specific refractive index of the material of the nanostructure, and the objective function, as an input variable, and configured to input the input variable into a predetermined algorithm to calculate design parameters of the nanostructure.

2. The mask design device for 3D proximity field pattering based on electric field control of claim 1, wherein the objective function executor is configured to select a plurality of points on the 2D electric field intensity map, and configured to execute the objective function based on the plurality of points.

3. The mask design device for 3D proximity field pattering based on electric field control of claim 1, wherein the objective function executor is configured to select a first point having the strongest electric field intensity in the 2D electric field intensity map, a second point having the weakest electric field intensity based on one axis, a third point having the weakest electric field intensity based on another axis, and a fourth point which is a center point of a virtual straight line connecting the second point and the third point, and configured to execute the objective function based on the first to fourth points.

4. The mask design device for 3D proximity field pattering based on electric field control of claim 3, wherein the objective function for being executed by the objective function executor is provided as FOM=Eₘₐₓ²+E_{diag}²−Eₘᵢₙₓ²−E_{minz}², wherein Eₘₐₓ² is an electric field at the first point, E_{diag}² is an electric field at the fourth point, Eₘᵢₙₓ² is an electric field at the second point, Eₘᵢₙₓ² is an electric field at the third point, and FOM is the objective function.

5. The mask design device for 3D proximity field pattering based on electric field control of claim 4, wherein the optimizer is configured to calculate a height of the nanostructure, based on which the objective function is maximized, as at least one of the design parameters of the nanostructure.

6. The mask design device for 3D proximity field pattering based on electric field control of claim 1, wherein the optimizer is configured to input the input variable into a particle swarm optimization (PSO) algorithm to calculate the design parameters of the nanostructure.

7. The mask design device for 3D proximity field pattering based on electric field control of claim 1, wherein the design parameters of the nanostructure calculated by the optimizer comprise a height of the nanostructure, a fill factor of the nanostructure, and a shape of the nanostructure.

8. A mask for 3D proximity field patterning based on electric field control, the mask comprising the nanostructure formed based on the design parameters calculated by the mask design device for 3D proximity field pattering based on electric field control of claim 1.

9. The mask for 3D proximity field patterning based on electric field control of claim 8, wherein the design parameters comprise a height of the nanostructure, a fill factor, and a shape of the nanostructure.

10. A nano patterning device, comprising:
a mask for 3D proximity field patterning based on electric field control, the mask comprising the nanostructure formed based on the design parameters calculated by the mask design device for 3D proximity field pattering based on electric field control of claim 1;
a light source configured to irradiate light towards the mask for 3D proximity field patterning based on electric field control; and
a photoresist configured to generate a pattern of the nanostructure, in response to the photoresist being irradiated with the light transmitted through the mask for 3D proximity field patterning based on electric field control and diffracted.

11. A method for manufacturing the mask for 3D proximity field patterning based on electric field control, the method comprising:
providing a master mold formed using the design parameters calculated by the mask design device for 3D proximity field pattering based on electric field control of claim 1 or using variables complementary to the design parameters;
depositing polyurethane acrylate on the master mold; and
curing the polyurethane acrylate and then separating the polyurethane acrylate from the master mold to produce the mask for 3D proximity field patterning based on electric field control formed of the polyurethane acrylate.

12. The method for manufacturing a mask for 3D proximity field patterning based on electric field control of claim 11, the method comprising:
depositing polydimethylsiloxane on the mask for 3D proximity field patterning based on electric field control; and
providing a second mask for 3D proximity field patterning based on electric field control formed of the polydimethylsiloxane by curing the polydimethylsiloxane and then separating the second mask for 3D proximity field patterning based on electric field control formed of the polyurethane acrylate.
